(19) United States
(12) Patent Application Publication
(10) Pub. No.: US 2009/0269621 A1
(43) Pub. Date: Oct. 29, 2009

(54) INTEGRATED DEVICE

(75) Inventors: Herbert Lifka, Eindhoven (NL); Albertus Adrianus Maria Dortmans, Eindhoven (NL); Eric Alexander Meulenkamp, Eindhoven (NL); Cristina Tanase, Eindhoven (NL)

Correspondence Address: Philips Intellectual Property and Standards, P.O. Box 3001, Briarcliff Manor, NY, 10510-8001, US

(73) Assignee: KONINKLIJKE PHILIPS ELECTRONICS N.V., Eindhoven (NL)

(21) Appl. No.: 12/373,920

(22) PCT Filed: Aug. 1, 2007
(86) PCT No.: PCT/IB07/53025

§ 371 Date: Jan. 15, 2009

(30) Foreign Application Priority Data
Aug. 8, 2006 (EP) 06118568.2

(51) Int. Cl. H01M 14/00

(52) U.S. Cl. 429/8

(57) ABSTRACT

The present invention relates to an integrated device (10) comprising at least one active organic element (14, 24, 26), a substrate supporting the at least one active organic element, a prefabricated thin battery (20) coupled to the at least one active organic element, and an encapsulation for sealing the integrated device, wherein one of the substrate and the encapsulation is formed by the prefabricated thin battery. This structure allows for a thin integrated device. The present invention also relates to a method for the manufacturing of such an integrated device.

### TECHNICAL FIELD OF THE INVENTION

The present invention relates to an integrated device comprising at least one active organic element and a thin battery coupled to the at least one active organic element. The present invention also relates to a method for the manufacturing of such an integrated device.

### BACKGROUND OF THE INVENTION

An example of a device comprising an active organic element and a battery is disclosed in the document WO03019658. More precisely, the device in WO03019658 comprises, from bottom to top, a substrate (such as glass or a flexible film), an energy carrier (battery or photovoltaic cell), a semitransparent insulation layer serving as a substrate for an organic light emitting diode (OLED), and finally an encapsulation or seal, which is comprised of glass. Upon operation, the energy carrier supplies a voltage that causes the OLED to emit light.

In one particular embodiment, the energy carrier and the OLED are produced on opposite sides of the semitransparent insulation layer, and the bottom substrate instead acts as a seal for the energy carrier. Thus, the OLED and the energy carrier are sealed separately. The sealing is necessary for avoiding influx of water and oxygen that otherwise would deteriorate the device performance.

However, the structure disclosed in WO03019658 yields a relatively thick and expensive package since the energy carrier and the OLED are encapsulated and sealed separately. To this end, for many applications, small thickness and low cost are important factors. Also, the energy carrier is fabricated with a thin film technology, which results in high cost.

### SUMMARY OF THE INVENTION

It is an object of the present invention to overcome this problem, and to provide an improved, integrated device with reduced thickness.

This and other objects that will be evident from the following description are achieved by means of an integrated device, and a method for the manufacturing of such an integrated device, according to the appended claims.

According to an aspect of the invention, there is provided an integrated device comprising at least one active organic element, a substrate supporting the at least one active organic element, a prefabricated thin battery coupled to the at least one active organic element, and an encapsulation for sealing the integrated device, wherein one of the substrate and the encapsulation is formed by the prefabricated thin battery.

Thus, the prefabricated battery gets the function also to act as top encapsulation of the device or act as a supporting and/or protective substrate of the device. This yields a thinner and more robust device compared to prior art structures since a separate encapsulation/substrate can be omitted. Due to the battery, the device may operate autonomously.

Preferably, the battery covers the complete active organic element area, so that it will not be exposed to water and/or air.

In one embodiment, the substrate is a transparent substrate, the at least one active organic element is processed on the transparent substrate, and the prefabricated thin battery is arranged on top of the at least one active organic element. Thus, here the prefabricated battery acts as the encapsulation of the integrated device. Further, the transparent substrate can be made of a flexible material, allowing the complete device to be flexible.

In another embodiment, the prefabricated thin battery is attached to the at least one active organic element, and an encapsulating coating is provided on the other side of the at least one active organic element compared to the battery. Thus, here the prefabricated battery acts as the substrate of the integrated device.

In one embodiment, the at least one active organic element is an OLED, and the battery is adapted to power the OLED. The OLED may for example be a display or a light source.

In another embodiment, the at least one active organic element is an organic sensor, and the battery is adapted to power the organic sensor. The sensor may for example be a photo-sensor, an organic switch, a rectifying diode, etc.

In another embodiment, the at least one active organic element is an organic photovoltaic cell, and the photovoltaic cell is adapted to charge the battery. In another embodiment, the at least one active organic element comprises an OLED and an organic photovoltaic cell arranged adjacent to each other, the organic photovoltaic cell is adapted to charge the battery, and the battery is adapted to power the OLED. The adjacent OLED and organic photovoltaic cell can advantageously be processed on the same substrate at the same time, which is very cost efficient.

In one embodiment, the device further comprises a second OLED provided on the other side of the thin battery compared to the at least one active organic element. Such a device may provide for a double-sided display (in case the first organic element also is an OLED), or a two color lamp, for example.

In one embodiment, a fixing agent is applied around the at least one active organic element and between the at least one active organic element and the prefabricated thin battery, which fixing agent comprises a getter material. The getter material is a water absorbing material, such as calcium oxide. Thus, the fixing agent serves to join the at least one active organic element and the prefabricated thin battery, as well as to protect the at least one active organic element from moisture from the sides of the device.

According to another aspect of the invention, there is provided a method for the manufacturing of an integrated device, comprising providing a transparent substrate, processing at least one active organic element on the transparent substrate, and arranging a prefabricated thin battery on top of the at least one active organic element for sealing the integrated device. Thus, here the prefabricated battery acts as the encapsulation of the integrated device.

In one embodiment, the method further comprises providing an encapsulating coating on the transparent substrate on the side of the substrate where the at least one active organic element is to be processed, and removing the transparent substrate after the at least one active organic element has been processed. Thus, here the prefabricated battery acts as the substrate of the integrated device. Preferably, the transparent substrate is removed after the prefabricated battery has been arranged on top of the at least one active organic element. The prefabricated thin battery may be arranged on top of the at least one active organic element by means of lamination, for example.

In one embodiment, the method further comprises filling the battery with electrolyte after the battery is laminated on top of the at least one active organic element. Before the battery is filled with the electrolyte, it is much flatter and will therefore laminate better, which in turn improves the sealing property of the battery.

### BRIEF DESCRIPTION OF THE DRAWINGS

These and other aspects of the present invention will now be described in more detail, with reference to the appended drawings showing currently preferred embodiments of the invention.

FIG. 1 is a schematic cross-sectional side view of an integrated device comprising a single active organic element according to an embodiment of the invention,

FIG. 2 is a schematic cross-sectional side view of an integrated device comprising an OLED and a photovoltaic cell according to another embodiment of the invention, and

FIGS. 3a-3b are schematic cross-sectional side views illustrating steps of manufacturing of an integrated device according to another embodiment of the invention.

### DETAILED DESCRIPTION OF EMBODIMENTS

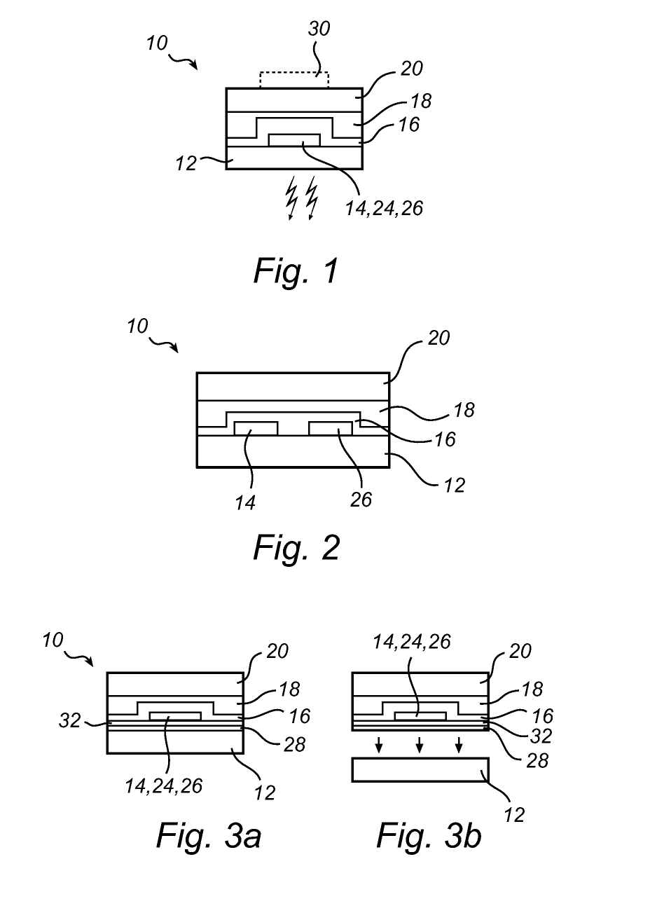

FIG. 1 is a cross-sectional side view of an integrated device 10 according to an embodiment of the invention. From bottom to top in FIG. 1, the integrated device 10 comprises a transparent substrate 12 onto which an organic light emitting diode (OLED) 14 is processed. The OLED 14 may be processed by means of printing or deposition or evaporation through a shadow mask, for example. The transparent substrate 12 may be made glass or plastics, for example. Also, it can be made of a flexible material, allowing the complete device 10 to be flexible, and the OLED 14 may function as a display or as a light source.

The substrate 12 and the OLED 14 are coated with a thin-film packaging layer 16, for example a NONON-stack (silicon nitride-silicon oxide-silicon nitride-silicon oxide-silicon nitride). On the layer 16, a topcoat 18 is applied, and on top of the topcoat 18, a prefabricated thin battery 20 is attached. The prefabricated thin battery 20 covers the complete OLED area. The topcoat 18 may function as a glue, and the prefabricated thin battery 20 is preferably laminated onto the topcoat 18. Also, a water absorbing getter material such as calcium oxide, CaO, may be incorporated in the glue 18, to protect the OLED 14 (or any other active organic element(s)) from moisture from the sides of the device. Also, a rim of standard glue (not shown) could be applied around the device except for the battery, to reduce water penetration and thereby further protect the device. The battery 20 is adapted to power the OLED 14 causing the OLED 14 to emit light (illustrated by arrows 22) during operation of the device 10. The battery 20 is prefabricated in a sense that incorporating the battery in the device mainly includes assembling the battery with the rest of the device.

No other coating or sealing has to be provided on top of the prefabricated battery 20. Thus, here the prefabricated thin battery 20 acts as a top side encapsulation of the device 10, avoiding the use of any dedicated top encapsulation or sealing. To this end, the prefabricated thin battery 20 should be flat and impermeable with respect to water (water tight) and/or air. An exemplary prefabricated battery having such properties is the Lithylene batteries by Philips. Also, in case the substrate 12 is flexible or omitted, the prefabricated battery should be flexible to realize a complete flexible device. Also, during manufacturing of the integrated device, for some batteries (such as the Lithylene battery, and NiCd— and NiMh batteries) it may be beneficial to fill the battery with electrolyte after mounting of the battery to the device, since the battery is much flatter without the electrolyte. It will then better laminate and therefore seal better.

In the integrated device 10 illustrated in FIG. 1, the thickness of the prefabricated battery 20 may be in the order of 500 μm, the thickness of the topcoat 18 in the order of 10 μm, the thickness of the layer 16 in the order of 1 μm, and the thickness of the substrate 12 in the order of 700 μm, rendering a total device thickness of about 1200 μm.

The above mentioned OLED 14 may in alternative embodiments be replaced by an organic sensor 24, such as a photo-sensor, or an organic photovoltaic cell (e.g. solar cell) 26. In the former case, the battery 20 powers the organic sensor 24, whereas in the latter case, the organic photovoltaic cell 26 charges the battery 20. Also, an additional OLED 30 may optionally be provided on the other side of the prefabricated battery 20 compared to the OLED 14/organic sensor 24/organic photovoltaic cell 26. Such a device may provide for a double-sided display (in case the first organic element also is an OLED), or a self powered lamp (in case the first organic element is a photovoltaic cell), for example.

FIG. 2 is a cross-sectional side view of an integrated device 10 according to another embodiment of the invention. The device of FIG. 2 is similar to that of FIG. 1, except in that an organic photovoltaic cell 26 is provided on the substrate 12 adjacent to the OLED 14. The prefabricated battery 20 still functions as top encapsulation of the device 10. The organic photovoltaic cell 26 is adapted to charge the battery 20, and the battery 20 is adapted to power the OLED 14. Thus, an autonomous device is realized. The anode and cathode (not shown) of the device 10 are preferably structured so as to allow separate coupling of the OLED 14 and the photovoltaic cell 26.

An OLED and an organic photovoltaic cell are structurally very similar. They both comprises a buffer layer and an organic active layer sandwiched between an anode and a cathode. The only difference is the type of organic active layer material. In an OLED, the organic active layer material is adapted to emit light (examples of such a material comprise derivatives of PPV and poly(fluorene)), whereas in an organic photovoltaic cell, the organic active layer material is adapted to convert light into electrical energy (an example of such a material comprises a conjugated polymer/fullerene blend). Therefore, the OLED 14 and organic photovoltaic cell 26 can advantageously be processed on the substrate 12 at the same time using the same processing steps, only using different organic active layer materials. The OLED 14 and organic photovoltaic cell 26 may for example be printed or evaporated through a shadow mask onto the substrate 12.

FIGS. 3a-3b are cross-sectional side views illustrating steps of manufacturing of an integrated device 10 according to another embodiment of the invention. The device 10 illustrated in FIG. 3a is similar to that of FIG. 1, except in that an encapsulating coating 32 and a polymer coating 28 are applied between the glass substrate 12 and the OLED 14/organic sensor 24/organic photovoltaic cell 26. The encapsulating coating 32 may be of the same material as the layer 16, and the polymer coating 28 may be made of polyimide. Conveniently, in manufacturing, the coatings are applied to the substrate 12 before the OLED 14/organic sensor 24/organic photovoltaic cell 26 is processed thereon. The substrate 12 may then be released from the polymer coating 28 by means of laser according to the EPLAR process (Electronics on Plastic by Laser Release) as illustrated in FIG. 3b, leaving a final device 10 without the substrate 12, where instead the prefabricated thin battery 20 acts as the device substrate. Without the glass substrate 12, a complete flexible integrated device 10 can be realized using a flexible battery. However, a rigid device without the substrate 12 is also contemplated.

There are many possible applications for the present invention. The small size of the integrated device makes it particularly useful for use in handheld apparatuses. For example, the integrated device with an OLED display may be incorporated in handheld electronic apparatus such as a mobile phone, a PDA, or a digital media player. The integrate device with one OLED display one each side of the battery (i.e. a double sided display) may be incorporated in a flip-phone. The integrated device with an OLED light source can be used as a standalone emergency light, reading light, underwater light, etc. The integrated device with an OLED and an organic photovoltaic cell can be used as a standalone lamp or display independent of an external power supply. The integrated device with an organic photovoltaic cell can for example be used as a renewable power source in various apparatuses, especially where small size is an issue, such as in an electronic credit card. The integrated device with an organic sensor may be used in combination with an OLED for switching or control purposes.

The person skilled in the art realizes that the present invention by no means is limited to the preferred embodiments described above. On the contrary, many modifications and variations are possible within the scope of the appended claims. For example, the prefabricated battery may act as a substrate and the glass substrate may be released (as explained in relation to FIGS. 3a-3b) also in the embodiment with both an OLED and an organic photovoltaic cell illustrated in FIG. 2. Also, several organic active elements, for example two or more OLEDs, may be provided on the substrate.

1. An integrated device, comprising:
at least one active organic element,
a substrate supporting the at least one active organic element,
a prefabricated thin battery coupled to the at least one active organic element, the battery sealingly encapsulating the integrated device.

2. An integrated device according to claim 1, wherein the battery covers the entire active organic element.

3. An integrated device according to claim 1, wherein the substrate is a transparent substrate, the at least one active organic element is processed on the transparent substrate, and the prefabricated thin battery is arranged on top of the at least one active organic element for sealing the integrated device.

4. An integrated device according to claim 3, wherein the transparent substrate is made of a flexible material.

5. An integrated device according to claim 1, wherein the prefabricated thin battery is attached to a first side of the at least one active organic element, whereby the battery acts as substrate, and an encapsulating coating is disposed over a second side of the at least one active organic element.

6. An integrated device according to claim 1, wherein the at least one active organic element is an OLED, and the battery is adapted to power the OLED.

7. An integrated device according to claim 1, wherein the at least one active organic element is an organic sensor, and the battery is adapted to power the organic sensor.

8. An integrated device according to claim 1, wherein the at least one active organic element is an organic photovoltaic cell, and the photovoltaic cell is adapted to charge the battery.

9. An integrated device according to claim 1, wherein the at least one active organic element comprises an OLED and an organic photovoltaic cell arranged adjacent to each other, the organic photovoltaic cell is adapted to charge the battery, and the battery is adapted to power the OLED.

10. (canceled)

11. An integrated device according to claim 1, wherein a fixing agent is applied around the at least one active organic element and between the at least one active organic element and the prefabricated thin battery, the fixing agent comprising a getter material.

12-16. (canceled)

17. An integrated device, comprising:
at least one active organic element,
a prefabricated thin battery coupled to the at least one active organic element, the battery supporting the at least one active organic element and sealingly encapsulating the integrated device.

18. An integrated device according to claim 17, wherein the battery covers the entire active organic element.
